(19) United States
(12) Patent Application Publication
(10) Pub. No.: US 2023/0230929 A1
(43) Pub. Date: Jul. 20, 2023

(54) PACKAGING PROCESS FOR EMBEDDED CHIPS

(71) Applicants: CHIA-MING LI, New Taipei City (TW); Guangdong ZECHENG Technology Co., LTD, Zhuhai (CN)

(72) Inventor: CHIA-MING LI, New Taipei City (TW)

(21) Appl. No.: 17/716,184

(22) Filed: Apr. 8, 2022

(30) Foreign Application Priority Data
Jan. 20, 2022 (TW) 111102463

(51) Int. Cl. H01L 23/538; H05K 3/38; H05K 3/46; H05K 1/11

(52) U.S. Cl. CPC H01L 23/5389; H05K 3/384; H05K 3/4652; H05K 1/115; H05K 2201/0355; H05K 2201/10674

(57) ABSTRACT

A packaging process for embedded chips includes: (1) mounting at least one IC chip on a circuit substrate, the IC chip having at least one exposed pin; (2) attaching a self-adhesive copper foil film to the surface of the circuit substrate, wherein the self-adhesive copper foil film has a copper foil layer and a B-stage insulating adhesive layer, the copper foil layer has at least one to-be-opened copper foil area corresponding to the pin, the insulating adhesive layer is applied on the copper foil layer, has no glass fiber, covers the IC chip, and has at least one to-be-opened insulating adhesive area corresponding to the pin, and the pin is in contact with the insulating adhesive layer but not with the copper foil layer; (3) removing the to-be-opened copper foil area; (4) removing the to-be-opened insulating adhesive area with an etching solution; and (5) curing the insulating adhesive layer completely.

### BACKGROUND OF THE INVENTION

### 1. Technical Field

The present invention relates to a technique for packaging embedded chips.

### 2. Description of Related Art

Unlike an IC (integrated circuit) chip that is mounted on the surface of a circuit board, an embedded chip package includes an IC chip embedded in a circuit board. To form electrical connection with the pins of the embedded IC chip, it is required that vias be formed in the circuit board at positions corresponding respectively to the pins and be plated with copper. Conventionally, those vias are formed by laser engraving, during whose process, however, the IC chip may be partially exposed to, and thus damaged by, laser irradiation. This conventional method, therefore, demands improvement.

### BRIEF SUMMARY OF THE INVENTION

In view of the above, the primary objective of the present invention is to provide a technique for packaging embedded IC chips without subjecting the chips to laser irradiation.

To achieve the foregoing and other objectives, the present invention provides a packaging process for embedded chips, wherein the packaging process includes the following steps:

(1) mounting at least one IC chip on the surface of a circuit substrate, wherein the IC chip has at least one exposed pin;

(2) attaching a self-adhesive copper foil film to the surface of the circuit substrate, wherein the self-adhesive copper foil film has a copper foil layer and a B-stage insulating adhesive layer, the insulating adhesive layer is applied on the copper foil layer and does not have glass fiber, the pin is in contact with the insulating adhesive layer but not in contact with the copper foil layer, the insulating adhesive layer covers the IC chip, the copper foil layer has at least one to-be-opened copper foil area corresponding to the pin, and the insulating adhesive layer has at least one to-be-opened insulating adhesive area corresponding to the pin;

(3) removing the to-be-opened copper foil area;

(4) removing the to-be-opened insulating adhesive area with an etching solution such that at least one via corresponding to the pin is formed in the self-adhesive copper foil film; and

(5) curing the insulating adhesive layer completely.

As the insulating adhesive layer used in the present invention does not have glass fiber and remains in the B stage when just attached to the circuit substrate, the to-be-opened insulating adhesive area can be removed with the etching solution, without having to resort to laser engraving; thus, the IC chip is kept from damage by laser irradiation.

### BRIEF DESCRIPTION OF THE SEVERAL VIEWS OF THE DRAWINGS

FIG. 1 to FIG. 9 show the packaging process according to an embodiment of the present invention.

### DETAILED DESCRIPTION OF THE INVENTION

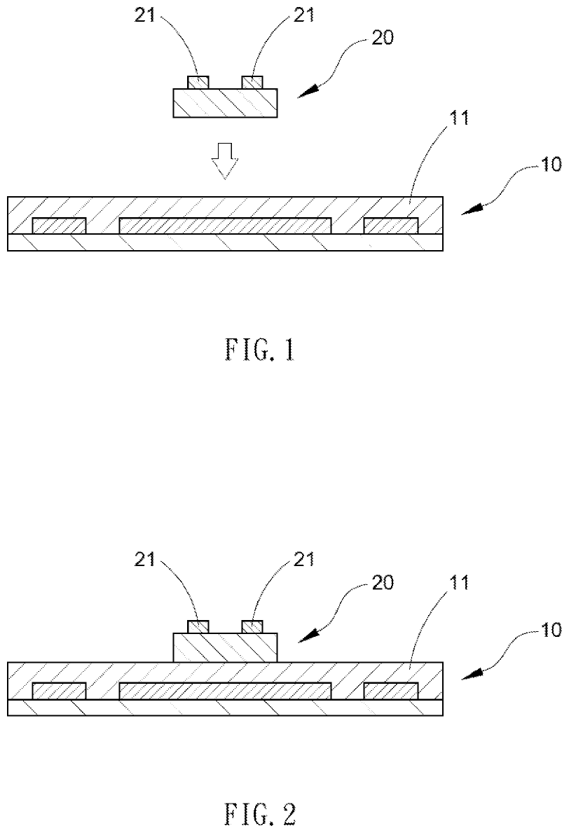

The present invention discloses a packaging process for embedded chips. The packaging process according to one embodiment of the invention is described below with reference to FIG. 1 to FIG. 9, in which the circuit designs are simplified to facilitate description; the actual circuit designs are not limited to those illustrated herein.

The embedded chip package structure in this embodiment is obtained through a packaging process that includes the following steps:

Step (1):

Referring to FIG. 1 and FIG. 2, at least one IC chip 20 is mounted on the surface of a circuit substrate 10. The IC chip 20 has at least one exposed pin 21. The exposed pin 21 is not in direct contact with the surface of the circuit substrate 10. The IC chip 20 is mounted on, for example but not necessarily, a dielectric layer 11 that constitutes the surface of the circuit substrate 10. The circuit substrate 10 may be made by any suitable method as required. The IC chip 20 may be, for example, an active device, a passive device, a microelectromechanical system (MEMS), or other chips.

Step (2):

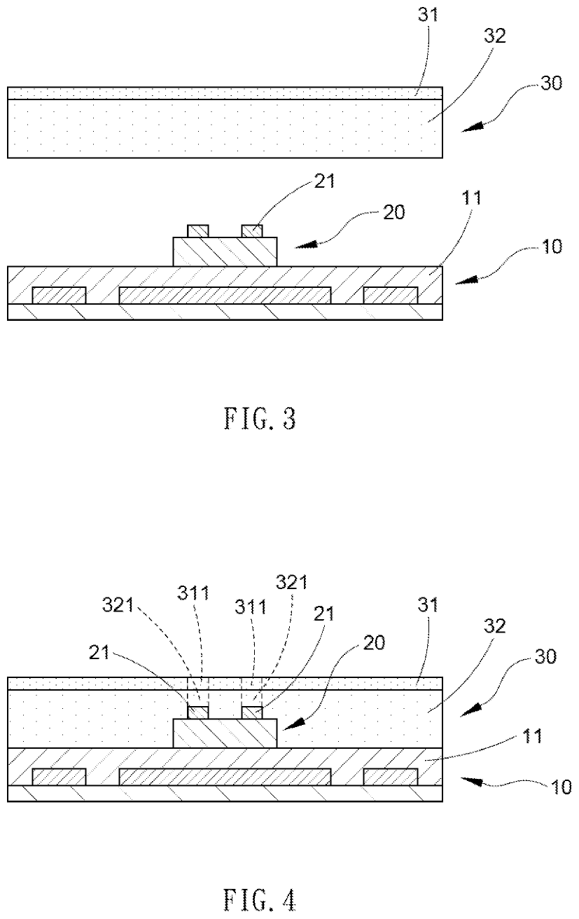

Referring to FIG. 3 and FIG. 4, a self-adhesive copper foil film 30 is attached to the surface of the circuit substrate 10. The self-adhesive copper foil film 30 has a copper foil layer 31 and a B-stage insulating adhesive layer 32. The insulating adhesive layer 32 is applied on the copper foil layer 31 and does not have glass fiber. The pin 21 is in contact with the insulating adhesive layer 32 but not in contact with the copper foil layer 31. The insulating adhesive layer 32 covers and encloses the IC chip 20. The insulating adhesive layer 32 may be, for example, an epoxy-based, acrylic-based, or polyimide-based photocuring and/or heat-curing resin. The term “B-stage” refers to a stage in which a curable resin is not completely cured but has been dried to such an extent that it is dry to the touch of a finger. Depending on its photocuring and/or heat-curing property, a B-stage resin can be completely cured by exposure to light of a specific wavelength and/or a specific curing temperature and thus enter the C stage. In the present invention, the insulating adhesive layer 32 stays in the B stage before step (5). The copper foil layer 31 has at least one to-be-opened copper foil area 311 corresponding to the pin 21, and the insulating adhesive layer 32 has at least one to-be-opened insulating adhesive area 321 corresponding to the pin 21. The to-be-opened insulating adhesive area 321 is covered by the to-be-opened copper foil area 311.

Step (3):

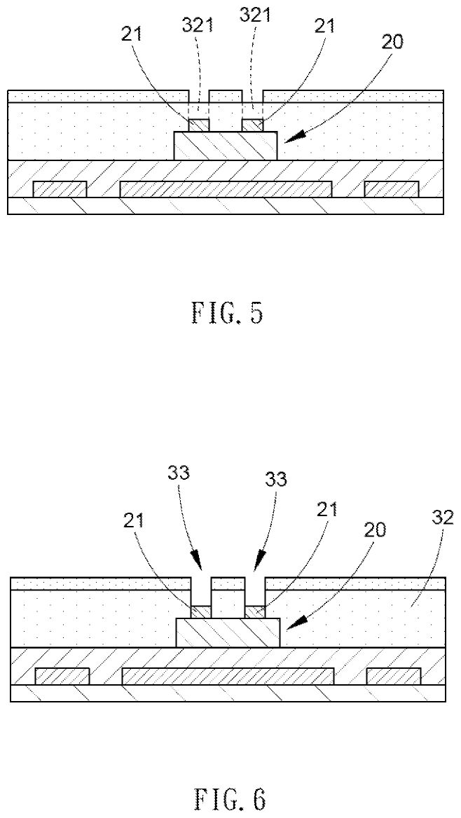

Referring to FIG. 5, the to-be-opened copper foil area 311 is removed to expose the to-be-opened insulating adhesive area 321. In one feasible embodiment, the to-be-opened copper foil area 311 is removed by a conventional method that includes applying a photoresist, exposure to light, development, and etching. The removing method, however, is not limited to the foregoing and may involve laser engraving instead.

Step (4):

Referring to FIG. 6, the to-be-opened insulating adhesive area 321 is removed with an etching solution such that at least one via 33 corresponding to the pin 21 is formed in the self-adhesive copper foil film 30. As used herein, the term “etching solution” refers to a preparation for removing the B-stage insulating adhesive layer portion in contact therewith. Once the to-be-opened insulating adhesive area 321 is removed, the pin 21 is exposed. It is worth mentioning that, in steps (3) and (4), the pin 21 and the other portions of the IC chip 20 will not be exposed to, and are therefore protected from damage by, laser irradiation.

Step (5):

Depending on its photocuring and/or heat-curing property, the B-stage insulating adhesive layer 32 is exposed to light of a specific wavelength and/or a specific curing temperature until completely cured. The cured insulating adhesive layer 32 is still in the shape shown in FIG. 6.

Step (6):

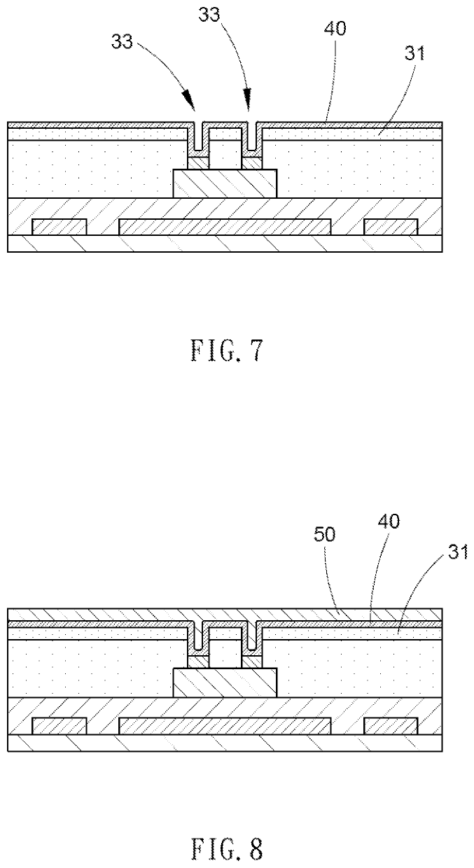

Referring to FIG. 7, an electrolessly plated copper layer 40 is formed on the copper foil layer 31 and in the via 33 by electroless plating.

Step (7):

Referring to FIG. 8, an electroplated copper layer 50 is formed on the electrolessly plated copper layer 40 by electroplating.

Step (8):

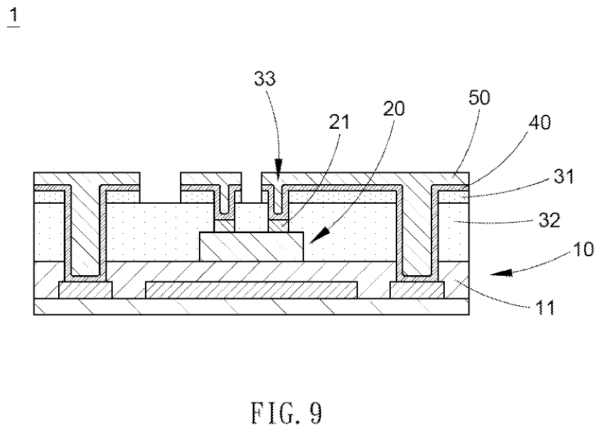

The copper foil layer 31, the electrolessly plated copper layer 40, and the electroplated copper layer 50 are subjected to a patterning process in order to enter the state shown in FIG. 9. The circuit substrate may be formed with another blind hole or a through hole, and this blind hole or through hole may be formed while steps (3) and (4) are performed. The process of forming such a blind or through hole is not shown in the accompanying drawings.

Once the foregoing steps are completed, the resulting embedded chip package structure 1 has one circuit substrate 10, at least one IC chip 20, one completely cured insulating adhesive layer 32, one copper foil layer 31, at least one via 33 formed in the insulating adhesive layer 32 and the copper foil layer 31, one electrolessly plated copper layer 40, and one electroplated copper layer 50, wherein: the IC chip 20 is mounted on the surface of the circuit substrate 10 and has at least one exposed pin 21, the insulating adhesive layer 32 does not have glass fiber, the pin 21 is in contact with the insulating adhesive layer 32 but not in contact with the copper foil layer 31, the insulating adhesive layer 32 covers and encloses the IC chip 20, the copper foil layer 31 covers the insulating adhesive layer 32, the via 33 corresponds to the pin 21, the electrolessly plated copper layer 40 is electrically connected between the pin 21 and the copper foil layer 31, and the electroplated copper layer 50 is formed on the electrolessly plated copper layer 40. The embedded chip package structure 1 may be further processed in order to meet its design requirements.

What is claimed is:

1. A packaging process for embedded chips, comprising the steps of:
(1) mounting at least one IC (integrated circuit) chip on a surface of a circuit substrate, wherein the IC chip has at least one exposed pin;
(2) attaching a self-adhesive copper foil film to the surface of the circuit substrate, wherein the self-adhesive copper foil film has a copper foil layer and a B-stage insulating adhesive layer, the insulating adhesive layer is applied on the copper foil layer, the insulating adhesive layer does not have glass fiber, the pin is in contact with the insulating adhesive layer but not in contact with the copper foil layer, the insulating adhesive layer covers the IC chip, the copper foil layer has at least one to-be-opened copper foil area corresponding to the pin, and the insulating adhesive layer has at least one to-be-opened insulating adhesive area corresponding to the pin;
(3) removing the to-be-opened copper foil area;
(4) removing the to-be-opened insulating adhesive area with an etching solution such that at least one via corresponding to the pin is formed in the self-adhesive copper foil film; and
(5) curing the insulating adhesive layer completely.

2. The packaging process for embedded chips as claimed in claim 1, further comprising the steps, to be performed after the step (5), of:
(6) forming an electrolessly plated copper layer on the copper foil layer and in the via by electroless plating; and
(7) forming an electroplated copper layer on the electrolessly plated copper layer by electroplating.

3. The packaging process for embedded chips as claimed in claim 2, further comprising the step, to be performed after the step (7), of:
(8) patterning the copper foil layer, the electrolessly plated copper layer, and the electroplated copper layer.
